(19) United States
(12) Patent Application Publication
(10) Pub. No.: US 2026/0321334 A1
(43) Pub. Date: Oct. 15, 2026

(54) ROM FAULT CHECK DURING MEMORY BOOT

(71) Applicant: Micron Technology, Inc., Boise, ID (US)

(72) Inventors: Pranjal Chauhan, Allen, TX (US); Arun Tom Abraham, Hyderabad (IN); Mahesh Rawal, Hyderabad (IN); Naveen Kodumuri, Hyderabad (IN); Tal Sharifie, Lehavim (IL); Jayaprakash Naradasi, Karnataka (IN); Yoav Weinberg, North York (CA); Andrew Chong, San Jose, CA (US)

(21) Appl. No.: 19/637,480

(22) Filed: Apr. 2, 2026

Related U.S. Application Data
(60) Provisional application No. 63/787,141, filed on Apr. 11, 2025.

(51) Int. Cl. G11C 29/38

(52) U.S. Cl. CPC G11C 29/38

(57) ABSTRACT

Memory system fault detection techniques are disclosed. In an example, a system can detect that a first hardware processor has executed code stored in a first read-only memory (ROM) and, in response to detecting that the first hardware processor has executed the code stored in the first ROM, trigger, by a second hardware processor, a ROM fault check on the first hardware processor. Prior to the memory system executing read or write requests received from a host system, the memory system can notify the host system about one or more ROM faults.

### PRIORITY APPLICATION

This application claims the benefit of priority to U.S. Provisional Application Ser. No. 63/787,141, filed Apr. 11, 2025, which is incorporated herein by reference in its entirety.

### TECHNICAL FIELD

This disclosure relates generally to memory devices and, more specifically, to fault detection systems for read-only memory (ROM) in safety-critical applications, such as automotive applications.

### BACKGROUND

A memory system can include one or more memory devices that store data. The memory devices can be, for example, non-volatile memory devices and volatile memory devices. In general, a host system can utilize a memory system to store data at the memory devices and to retrieve data from the memory devices.

### BRIEF DESCRIPTION OF THE DRAWINGS

The disclosure will be understood more fully from the detailed description given below and from the accompanying drawings of various examples of the disclosure. The drawings, however, should not be taken to limit the disclosure to the specific examples, but are for explanation and understanding only.

FIG. 1 is a block diagram illustrating an example computing system that includes a memory system, in accordance with some examples.

FIG. 2 is a diagram of a memory system, in accordance with some examples.

FIG. 3 illustrates a diagram of a routine (process or method) performed using the safety monitor component, in accordance with some examples.

FIG. 4 illustrates a diagram of a routine (process or method) performed using the safety monitor component, in accordance with some examples.

FIG. 5 is a block diagram of an example computer system, in accordance with some examples.

### DETAILED DESCRIPTION

The present disclosure introduces an innovative approach to ROM fault detection in memory systems, such as in automotive memory systems. The disclosed system uses multiple hardware processors of a memory system together to perform fault detection efficiently. After power-up initialization or in response to receiving a vendor-specific (VS) command, a first hardware processor (e.g., a power management unit (PMU) central processing unit (CPU)) of the multiple hardware processors executes its ROM code. Then, a second hardware processor of the multiple hardware processors can trigger fault detection on the first hardware processor after the first hardware processor finishes executing the ROM code. The second hardware processor can trigger this fault detection while the second hardware processor executes its own ROM code. This parallel processing capability allows the memory system to optimize boot time while maintaining robust fault detection. In some cases, the first hardware processor can trigger fault detection on the second hardware processor before or after the first hardware processor completes booting up. The architecture leverages existing hardware resources, particularly Memory Built-In Self-Test (MBIST) capabilities that are already present for manufacturing testing, eliminating the need for dedicated fault detection circuits. When ROM faults are detected, the memory system (e.g., a firmware (FW) processor and/or one of the multiple hardware processors) can notify a host system about the ROM faults through any one of multiple paths. These paths can include memory device error responses, sideband signals (GPIO), or dropping the link if a hardware processor becomes non-functional.

An advantage of this approach is its flexibility in fault detection timing. Rather than performing all fault checks before ROM execution, which can significantly impact boot time, the memory system allows hardware processors to execute their ROM code first and then coordinate fault checking when they become available. This is particularly effective in multi-processor systems, where one ROM can trigger fault detection on another ROM versus traditional single-ROM implementations that rely on hardware or firmware triggers after ROM execution. The system can be designed for automotive applications that may require functional safety (FS) compliance, ensuring that all ROM faults are detected before any data transfer occurs between the host system and the memory system (or memory device). This prevents corrupted data transfer while maintaining optimal boot time through efficient parallel processing and hardware-controlled architecture that operates independently of FW.

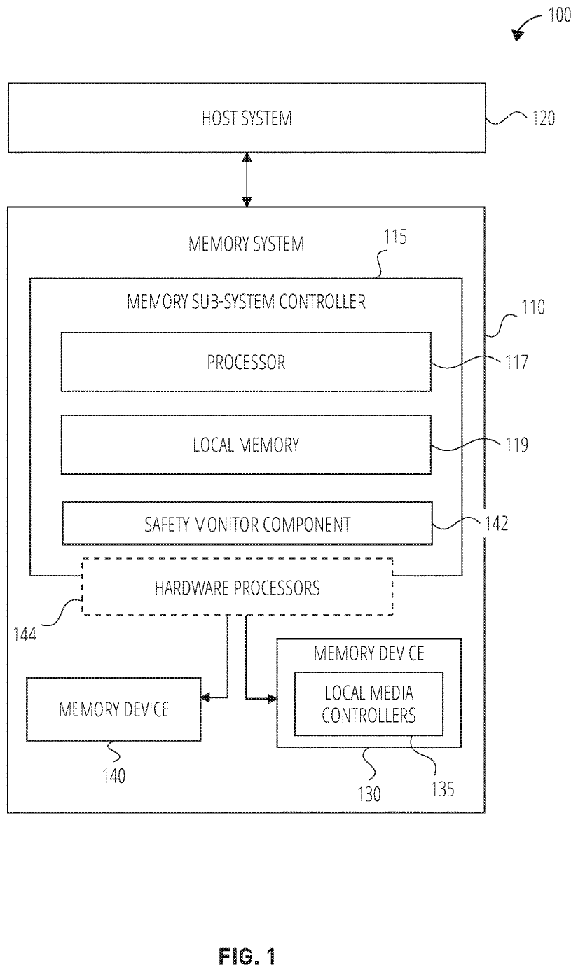

A memory system can be a storage device, a memory module (memory component), or a hybrid of a storage device and memory module. Examples of storage devices and memory modules are described below in conjunction with FIG. 1. In general, a host system can utilize a memory system that includes one or more memory components, such as memory devices (e.g., memory dies or planes across multiple memory dies) that store data. The host system can send access requests (e.g., write command, read command) to the memory system, such as to store data at the memory system and to read data from the memory system.

A memory device can be a non-volatile memory device. A non-volatile memory device is a package of one or more dice (or dies). Each die can be comprised of one or more planes. For some types of non-volatile memory devices (e.g., NAND devices), each plane is comprised of a set of physical blocks. For some memory devices, blocks are the smallest areas that can be erased. Such blocks can be referred to or addressed as logical units (LUN). Each block is comprised of a set of pages. Each page is comprised of a set of memory cells, which store bits of data. The memory devices can be raw memory devices (e.g., NAND), which are managed externally, for example, by an external controller. The memory devices can be managed memory devices (e.g., managed NAND), which are raw memory device combined with a local embedded controller for memory management within the same memory device package.

In automotive memory devices and memory systems, conventional ROM fault detection approaches face several significant challenges and inefficiencies. These methods usually check ROM faults before executing any ROM code by the hardware processors. This substantially increases boot time in systems with multiple CPUs (also referred to as hardware processors). This sequential approach of checking then executing creates unnecessary delays in the initialization process.

Some implementations use dedicated hardware circuits for fault detection during mission mode, leading to increased die size and system costs. The addition of hardware safety mechanisms such as error correction code (ECC) and parity checking circuits creates overhead in terms of both area and power consumption. This becomes particularly problematic in automotive applications where space and resource constraints are critical considerations. Furthermore, existing approaches typically rely on FW-based fault detection methods, such as reading and comparing ROM data with reference code (sometimes referred to as “golden” code or ground-truth code). While this method eliminates the need for additional hardware, it can be very time-consuming and can significantly and adversely impact the boot time of the memory device. This creates a challenging trade-off between thorough fault detection and system performance.

These inefficiencies are particularly problematic in safety-critical automotive applications where both reliability and quick initialization times are important considerations. The lack of efficient fault detection mechanisms that can operate within boot time constraints represents a significant challenge in current automotive memory systems and/or any other memory systems.

Mission mode refers to the operational state of the memory device after it has been shipped to a customer and is being used in its intended application. During mission mode, the memory device is performing normal operations like reading and writing data between the host system and memory device. This is distinct from manufacturing testing or initial boot phases. In some examples, the memory device can perform ROM fault checks during mission mode through vendor-specific (VS) commands from the host system, such as reset/reboot requests. This allows for safety verification of ROM contents while the device is deployed in the field, which is particularly important for automotive applications requiring functional safety compliance. During mission mode, existing Memory Built-In Self-Test (MBIST) hardware that was originally used for manufacturing testing can be repurposed to detect ROM faults before any data transfer occurs between the host and memory device. This provides an area-efficient way to verify ROM integrity during normal operation without requiring additional dedicated fault detection circuits.

Specifically, the present disclosure includes a ROM fault detection architecture that enables parallel processing and optimizes boot time, such as in automotive memory systems. The architecture allows ROM code execution before fault checking, with one processor triggering fault detection on another processor or another processor's ROM while that processor is idle. This can avoid the sequential approach of checking the ROM before executing the code stored in the ROM. Examples discussed herein can leverage MBIST hardware that may already be present for manufacturing testing, which can avoid the need for additional dedicated fault detection circuits to be added and can reduce memory die size. The disclosed architecture can provide multiple notification paths to the host system through memory device error responses, sideband signals (GPIO), or link drops, ensuring robust fault detection while maintaining compliance with certain standards. By enabling parallel processing and utilizing existing hardware resources, the disclosed system achieves improved boot time and area efficiency while ensuring all ROM faults are detected before any data transfer occurs (e.g., any host reads or writes are serviced) between the host and the memory system.

In some examples, a memory system is provided that includes multiple hardware processors, each with an associated ROM. During operation, a first hardware processor executes code from its ROM while a second hardware processor monitors its execution status. After the first processor completes ROM execution, the second hardware processor triggers fault detection on the first hardware processor while continuing to execute its own ROM code in parallel, optimizing boot time through concurrent processing.

The fault detection can be performed through multiple methods, including firmware-based comparison with golden ROM code and/or hardware-based MBIST. The system can leverage existing MBIST hardware used for manufacturing testing, eliminating the need for additional dedicated fault detection circuits. Controller safety mechanisms including parity checking, CRC, ECC, timeout monitoring, single error correction double error detection (SECDED), voltage monitoring, and temperature sensing provide additional fault detection, such as during ROM execution.

In some cases, when ROM faults are detected, the disclosed system can employ any one of multiple notification paths to alert the host system before any data transfer occurs. These include sending memory device error responses after attempting to execute commands from the command queue, asserting sideband signals (GPIO) for improved response time, and/or dropping the link between the memory system and host system, such as if a hardware processor becomes non-functional. The disclosed system can verify fault check signatures (e.g., MBIST signatures) along with status information to avoid false positives.

The memory system can be configured to initiate a ROM fault check. A ROM fault check can refer to or include a diagnostic test that is configured to verify the integrity of the data stored in a ROM. In an example, a ROM fault check can be used to check if the software stored within the ROM is valid or corrupted. In an automotive environment, a response to a ROM fault check can include an error code indicating a compromised function, such as to indicate a problem with an engine control module ROM or other ROM. In an example, the memory system can receive VS commands from the host system, such as during mission mode, and in response the memory system can trigger a ROM fault check. These VS commands may include reset/reboot requests or other specialized instructions. The fault detection can also be triggered during memory sub-system or memory device initialization through hardware, ROM, or FW mechanisms. This architecture is particularly suited for automotive applications requiring FS compliance, where preventing corrupted data transfer between host and memory device is critical.

For multi-processor configurations, after and/or before completing its own fault detection responsibilities, the first hardware processor can similarly monitor the second hardware processor's ROM execution and trigger fault detection when appropriate, establishing a reciprocal checking relationship. In some cases, the first hardware processor can trigger fault detection on the second hardware processor independent on fault checking performed by the first hardware processor and vice versa. This parallel processing capability, combined with the use of existing hardware resources and multiple notification paths, creates an efficient and robust fault detection system for the memory system.

Though various examples are described herein as being implemented with respect to a memory system (e.g., a controller of the memory system), some or all of the portions of an embodiment can be implemented with respect to a host system, such as a software application or an operating system of the host system.

FIG. 1 illustrates an example computing system 100 that includes a memory system 110, in accordance with some examples. The memory system 110 can include media, such as one or more volatile memory devices (e.g., memory device 140), one or more non-volatile memory devices (e.g., memory device 130), or a combination of such. The memory system 110 includes a memory sub-system controller 115 that contains several key components for implementing the ROM fault detection system. While memory sub-system controller 115 is shown as a single component, the memory sub-system controller 115 (and/or any of its subcomponents, such as processor 117) can be included as one or more hardware processors of the hardware processors 144.

The hardware processors 144 can include any combination of one or more of a PMU processor configured to handle power management operations and initial boot sequences; a high-speed (HS) processor configured to load and execute firmware and handle high-speed operations; one or more channel processors coupled between the memory sub-system controller 115 and memory devices 130 to process backend data from NAND memory; multiple CPUs for different power domains, where one CPU handles power management while others handle firmware configuration and channel operations; local media controllers 135 that operate in conjunction with the memory sub-system controller 115 to execute operations on memory cells; multiple processors operating in parallel or sequential configurations based on system requirements, where some processors handle initialization while others manage data transfer operations; safety-critical processors (implemented as part of the safety monitor component 142) configured to implement controller safety mechanisms including parity checking, cyclic redundancy code (CRC), ECC, timeout monitoring, voltage monitoring; temperature sensing, firmware processors (e.g., processor 117) responsible for loading FW from external boot devices and configuring system operations; and/or multiple channel processors that can be connected to handle different NAND channels and process backend data transfers. The hardware processors 144 can be configured to operate independently or in coordination with each other, with some hardware processors triggering fault detection on others' ROMs while continuing their own operations in parallel.

Triggering fault detection on a ROM can begin with initializing the ROM firmware and enabling system clocks. The memory sub-system 110 can first check voltage stability to ensure proper operating conditions before initiating any fault detection operations. After these preliminary checks are complete, the memory sub-system 110 can activate the MBIST hardware to perform fault detection on ROMs that are currently idle. The MBIST hardware can be included or be part of one or more components of the memory system 110 as needed to carry out self-test operations. During the fault detection process, the memory sub-system 110 employs multiple verification methods. The primary approach can use MBIST hardware to check for manufacturing defects and potential faults in the ROM. Controller safety mechanisms including parity checking, CRC, ECC, SECDED, and various monitoring systems can run continuously during ROM execution to detect any faults that may occur. For a more thorough but time-consuming verification, the memory sub-system 110 can perform FW-based checks by reading ROM data and comparing it against golden (ground-truth) ROM code.

The verification process can include collecting ROM BIST (built-in self-test) status information and reading a BIST signature that has been loaded into system memory, such as in the local memory 119. This signature can be compared against a reference or golden signature, with specific checks to ensure the signature value is non-zero, preventing false positive results. The memory sub-system 110 can trigger these fault detection operations through multiple channels, such as during device initialization via hardware, through firmware after ROM execution, by other CPU ROMs when processors become available, and/or through vendor-specific commands received from the host system 120, such as during mission mode. If any faults are detected, the system employs a multi-layered notification approach. The memory sub-system controller 115 can send error responses through the interface with the host system 120, assert sideband signals (GPIO) for improved response time to the automotive control system, and/or initiate a link drop if one or more of the hardware processors 144 become non-functional due to ROM faults. This comprehensive approach ensures reliable fault detection while maintaining optimal boot time through parallel processing capabilities.

A memory system 110 can be a storage device, a memory module, or a hybrid of a storage device and memory module. Examples of a storage device include a solid-state drive (SSD), a flash drive, a universal serial bus (USB) flash drive, a secure digital (SD) card, an embedded Multi-Media Controller (eMMC) drive, a Universal Flash Storage (UFS) drive, and a hard disk drive (HDD). Examples of memory modules include a dual in-line memory module (DIMM), a small outline DIMM (SO-DIMM), and various types of non-volatile dual in-line memory module (NVDIMM).

The computing system 100 can be a computing device such as a desktop computer, laptop computer, network server, mobile device, a vehicle (e.g., airplane, drone, train, automobile, or other conveyance), Internet of Things (IoT) enabled device, embedded computer (e.g., one included in a vehicle, industrial equipment, or a networked commercial device), or such computing device that includes memory and a processing device.

The computing system 100 can include a host system 120 that is coupled to one or more memory systems 110. In some examples, the host system 120 is coupled to different types of memory systems 110. FIG. 1 illustrates one example of a host system 120 coupled to one memory system 110.

The host system 120 can include a processor chipset and a software stack executed by the processor chipset. The processor chipset can include one or more cores, one or more caches, a memory controller (e.g., NVDIMM controller), and a storage protocol controller (e.g., a peripheral component interconnect express (PCIe) controller, serial advanced technology attachment (SATA) controller). The host system 120 uses the memory system 110, for example, to write data to the memory system 110 and read data from the memory system 110.

The host system 120 can include or be coupled to the memory system 110 so that the host system 120 can read data from or write data to the memory system 110. The host system 120 can be coupled to the memory system 110 via a physical host interface. Examples of a physical host interface include, but are not limited to, a SATA) interface, a PCIe interface, a compute express link (CXL) interface, a USB interface, a Fibre Channel interface, a Serial Attached SCSI (SAS) interface, etc. The physical host interface can be used to transmit data between the host system 120 and the memory system 110. The host system 120 can further utilize an NVM Express (NVMe) interface to access the memory devices 130, 140 when the memory system 110 is coupled with the host system 120 by the PCIe or CXL interface. The physical host interface can provide an interface for passing control, address, data, and other signals between the memory system 110 and the host system 120.

The memory devices 130, 140 can include any combination of the different types of non-volatile memory devices and/or volatile memory devices. The volatile memory devices (e.g., memory device 140) can be, but are not limited to, random access memory (RAM), such as dynamic random access memory (DRAM) and synchronous dynamic random access memory (SDRAM).

Some examples of non-volatile memory devices (e.g., memory device 130) include a NAND flash memory and write-in-place memory, such as a three-dimensional (3D) cross-point memory device, which is a cross-point array of non-volatile memory cells. A cross-point array of non-volatile memory can perform bit storage based on a change of bulk resistance, in conjunction with a stackable cross-gridded data access array. Additionally, in contrast to many flash-based memories, cross-point non-volatile memory can perform a write in-place operation, where a non-volatile memory cell can be programmed without the non-volatile memory cell being previously erased. NAND type flash memory includes, for example, two-dimensional (2D) NAND and 3D NAND.

Each of the memory devices 130, 140 can include one or more arrays of memory cells. One type of memory cell, for example, single level cells (SLCs), can store one bit per cell. Other types of memory cells such as, dual SLC with pillar float, multi-level cells (MLCs), tri-level cells (TLCs), quad-level cells (QLCs), and/or penta-level cells (PLCs), can store multiple bits per cell. In some examples, each of the memory devices 130, 140 can include one or more arrays of memory cells such as SLCs, MLCs, TLCs, QLCs, or any combination of such. In some examples, a particular memory device can include an SLC portion, and an MLC portion, a TLC portion, or a QLC portion of memory cells. The memory cells of the memory devices 130, 140 can be grouped as pages that can refer to a logical unit of the memory device used to store data. With some types of memory (e.g., NAND), pages can be grouped to form blocks or BSs. As used herein, a block comprising SLCs can be referred to as a SLC block, a block including MLCs can be referred to as a MLC block, a block comprising TLCs can be referred to as a TLC block, and a block including QLCs can be referred to as a QLC block.

Although non-volatile memory components such as NAND-type flash memory (e.g., 2D NAND, 3D NAND) and 3D cross-point array of non-volatile memory cells are described, the memory device 130 can be based on any other type of non-volatile memory, such as ROM, phase change memory (PCM), self-selecting memory, other chalcogenide-based memories, ferroelectric transistor random-access memory (FeTRAM), ferroelectric random access memory (FeRAM), magneto random access memory (MRAM), Spin Transfer Torque (STT)-MRAM, conductive bridging RAM (CBRAM), resistive random access memory (ReRAM), oxide-based RRAM (OxRAM), negative-or (NOR) flash memory, and electrically erasable programmable read-only memory (EEPROM).

A memory sub-system controller 115 (or controller for simplicity) can communicate with the memory devices 130, 140 to perform operations such as reading data, writing data, or erasing data (e.g., performing garbage collection (GC) operations) at the memory devices 130, 140 and other such operations. The memory sub-system controller 115 can include hardware such as one or more integrated circuits and/or discrete components, a buffer memory, or a combination thereof. The hardware can include digital circuitry with dedicated (e.g., hard-coded) logic to perform the operations described herein. The memory sub-system controller 115 can be a microcontroller, special purpose logic circuitry (e.g., a field programmable gate array (FPGA), an application specific integrated circuit (ASIC), etc.), or other suitable processor.

The memory sub-system controller 115 can include a processor 117 (e.g., processing device) configured to (or programmed to) execute instructions stored in local memory 119. In the illustrated example, the local memory 119 of the memory sub-system controller 115 includes an embedded memory configured to store instructions for performing various processes, operations, logic flows, and routines that control operation of the memory system 110, including handling communications between the memory system 110 and the host system 120.

In some examples, the local memory 119 can include memory registers storing memory pointers, fetched data, and so forth. The local memory 119 can also include ROM for storing micro-code. While the example memory system 110 in FIG. 1 has been illustrated as including the memory sub-system controller 115, in another example, a memory system 110 does not include a memory sub-system controller 115, and can instead rely upon external control (e.g., provided by an external host, or by a processor or controller separate from the memory system).

In general, the memory sub-system controller 115 can receive commands or operations from the host system 120 and can convert the commands or operations into instructions or appropriate commands to achieve the desired access to the memory device 130 and/or the memory device 140. The memory sub-system controller 115 can be responsible for other operations such as wear leveling operations, GC operations, error detection and ECC operations, encryption operations, caching operations, and address translations between a logical address (e.g., logical block address (LBA), namespace) and a physical memory address (e.g., physical block address in a physical address space of the memory device 130 or memory device 140) that are associated with the memory devices 130, 140. The memory sub-system controller 115 can further include host interface circuitry to communicate with the host system 120 via the physical host interface. The host interface circuitry can convert the commands received from the host system 120 into command instructions to access the memory device 130 and/or the memory device 140 as well as convert responses associated with the memory device 130 and/or the memory device 140 into information for the host system 120.

The memory system 110 can also include additional circuitry or components that are not illustrated. In some examples, the memory system 110 can include a cache or buffer (e.g., DRAM) and address circuitry (e.g., a row decoder and a column decoder) that can receive an address from the memory sub-system controller 115 and decode the address to access the memory devices 130, 140.

In some examples, the memory device 130 includes local media controllers 135 that operate in conjunction with memory sub-system controller 115 to execute operations on one or more memory cells of the memory device 130. An external controller (e.g., memory sub-system controller 115) can externally manage the memory device 130 (e.g., perform media management operations on the memory device 130). In some examples, a memory device 130 is a managed memory device, which is a raw memory device combined with a local controller (e.g., local media controller 135) for media management within the same memory device package. An example of a managed memory device is a managed NAND (MNAND) device. Any operation discussed as being performed by the memory sub-system controller 115 can be similarly performed by the local media controllers 135 and vice versa.

Any discussion with respect to the memory device 130 can similarly be applied to the memory device 140. Any function pertaining to the local media controllers 135 can, in some cases, be performed by the device) memory sub-system controller 115.

The memory sub-system controller 115 can include or use a safety monitor component 142 to manage ROM fault detection operations. The memory sub-system controller 115 also includes hardware processors 144. Each of the hardware processors 144 can be configured to execute ROM code and perform fault detection checks on one or more other processors or ROMs, as discussed below. The safety monitor component 142 coordinates the ROM fault detection process between the hardware processors 144. When one processor completes ROM execution, another processor can trigger fault detection on the completed ROM while continuing to execute its own ROM code. This parallel processing approach optimizes boot time while maintaining robust fault detection capabilities. The safety monitor component 142 can employ multiple methods to notify the host system 120 of ROM faults, including memory device error responses, sideband signals, or link drops.

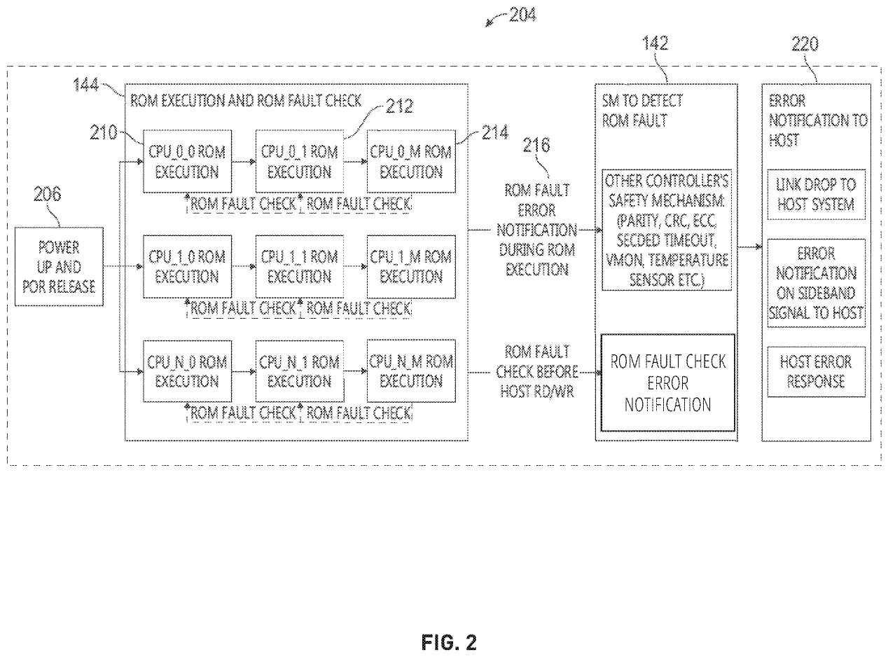

FIG. 2 is a diagram 204 of the memory system 110, in accordance with some examples. Specifically, the diagram 204 details ROM execution and fault checking operations within the memory system 110 shown in FIG. 1. The diagram 204 shows the interaction between multiple hardware processors 144 and the safety monitor component 142 during the boot process and/or during a fault checking operation that can be triggered in response to a VS command received from the host system 120.

In some examples, the process begins with a power up and POR (Power-On Reset) release 206, which initiates the boot sequence for all hardware processors 144. Following this, multiple CPU ROM execution blocks, such as first hardware processor 210, second hardware processor 212, and third hardware processor 214 can begin executing their respective ROM codes. For example, the first hardware processor 210 can access a first ROM to retrieve and execute a first set of instructions stored in the first ROM. Similarly, the second hardware processor 212 can access a second ROM to retrieve and execute a second set of instructions stored in the second ROM. The third hardware processor 214 can access a third ROM to retrieve and execute a third set of instructions stored in the third ROM. In some cases, the second hardware processor 212 waits for the first hardware processor 210 to finish executing the first set of instructions before starting to execute the second set of instructions. In some cases, the second hardware processor 212 executes the second set of instructions in parallel with the first hardware processor 210 executing the first set of instructions.

The diagram 204 depicts three rows of CPU ROM execution blocks, labeled as CPU_0_0 through CPU_0_M, CPU_1_0 through CPU_1_M, and CPU_N_0 through CPU_N_M. This structure illustrates how multiple hardware processors 144 can operate either sequentially and/or in parallel, depending on system requirements. Namely, the diagram 204 depicts three distinct CPUs (CPU_0, CPU_1, and CPU_N), each capable of executing multiple ROM operations and fault checks in sequence. Each CPU row shows a progression of ROM execution blocks (from _0 through _M) that represent sequential operations for that particular CPU.

While the CPUs can operate in parallel with each other, the ROM execution and fault checking operations within each individual CPU can occur sequentially. For example, CPU_0 will execute its ROM code blocks in sequence (CPU_0_0 through CPU_0_M), while CPU_1 can simultaneously execute its own sequence of ROM operations (CPU_1_0 through CPU_1_M). The dotted lines between the CPU rows indicate ROM fault check paths, showing how one CPU can trigger fault detection on another CPU's ROM while continuing its own execution sequence. This architecture enables parallel processing between CPUs while maintaining sequential execution within each CPU's operations, optimizing boot time through efficient coordination of ROM execution and fault checking activities.

This approach is particularly effective in multi-processor configurations where different CPUs have distinct roles, for example, one CPU handling power management while others manage firmware configuration and channel operations. The sequential nature of each CPU's operations ensures proper initialization and fault checking, while the parallel operation between CPUs helps maintain optimal boot time performance.

Between these ROM execution blocks are dotted lines indicating ROM fault check paths. These paths show how one hardware processor can trigger fault detection on another processor's ROM (as discussed above) while continuing its own execution, enabling parallel processing and optimizing boot time.

For example, the hardware processors 144 can include a two-processor system with a PMU processor and a HS processor among other processors. After power-up initialization, the PMU processor can execute its ROM code for initial boot operations. Once it completes execution, it becomes available for fault checking. The PMU processor can send a message or communication to the HS processor indicating that the PMU processor has become idle and/or has finished executing the ROM code. At this point, the HS processor, which can be executing its own ROM code and/or performing other operations, can trigger MBIST on the PMU processor's ROM. The HS processor initiates this by enabling clocks, checking voltage stability, and activating the MBIST hardware of the PMU processor.

While the MBIST runs on the PMU processor, the HS processor continues executing its own ROM code and other initialization tasks in parallel. After the PMU processor completes the MBIST operations, the PMU processor can update a status indicating completion and whether the MBIST operations completed successfully (e.g., indicating the lack of ROM faults or indicated presence of one or more ROM faults). In some examples, the PMU processor stores a signature representing a result of executing the MBIST operations in a register. The HS processor can collect the MBIST status (e.g., by accessing the register storing this information from the PMU processor) and verify the signature against a golden signature to ensure there are no false positives and/or to verify presence of ROM faults.

Similarly, after the HS processor completes its ROM execution, the PMU processor (which is now idle) can trigger MBIST on the HS processor's ROM. The PMU processor follows the same sequence, such as initializing ROM firmware, enabling clocks, checking voltage stability, and triggering MBIST on the HS processor while continuing its other operations. This creates an efficient cross-checking system where processors verify each other's status while maintaining parallel operation.

If any faults are detected during this process, the memory system 110, such as via the safety monitor component 142, can immediately notify the host through one or more channels. For example, the safety monitor component 142 can send error responses through the memory device interface, assert sideband signals (GPIO), and/or initiate a link drop. This comprehensive approach ensures reliable fault detection while maintaining optimal boot time through efficient parallel processing. This architecture is particularly effective because it leverages existing MBIST hardware and enables fault checking to occur naturally when processors become available, rather than forcing sequential checking before execution.

For example, when ROM faults are detected, the safety monitor component 142 can use a notification system to alert the host system 120. The memory device error response channel operates by first accessing pending read or write commands from the host system's command queue (e.g., a command queue of the memory system 110 that stores pending read or write commands). The safety monitor component 142 attempts to execute these commands. Upon detecting ROM faults and/or in response to determining that the commands are not successfully executed or completed and/or that the commands time out, the safety monitor component 142 can generate and send appropriate error responses back to the host system 120 through the normal command-response interface.

For time-critical notifications, the safety monitor component 142 can use a sideband signal channel using GPIO. This process begins with ROM firmware initialization and clock enabling, followed by voltage stability verification. The safety monitor component 142 then collects ROM BIST status information and performs signature verification against a golden signature. Upon confirming a fault condition, the safety monitor component 142 can assert a dedicated GPIO signal to provide rapid notification to the automotive control system (e.g., the host system 120).

The link drop channel serves as a critical failsafe mechanism for severe faults. During ROM execution, the safety monitor component 142 continuously monitors processor functionality. If a processor becomes non-functional due to ROM faults, then the safety monitor component 142 asserts a reset to the link interface and drops the communication link between the memory system 110 and host system 120. This causes the host system 120 to detect a timeout condition, effectively preventing any potential corrupted data transfer.

The safety monitor component 142 can use these or other notification channels based on fault severity and type. For recoverable faults encountered during normal operation, it uses error responses through the standard interface. Time-critical situations trigger immediate sideband signal notifications, while severe faults that compromise processor functionality result in link drops.

This multi-channel approach ensures reliable fault notification while maintaining optimal boot time through several key features: parallel processing capabilities that allow fault checking to occur alongside other operations, a hardware-controlled architecture that operates independently of firmware, and multiple notification paths that can handle different fault scenarios. In an example, the memory system 110 prevents any corrupted data transfer between the host system 120 and memory system 110, maintaining the integrity of the automotive memory system.

The safety monitor component 142 is represented in the middle section of the diagram 204, showing its role in detecting ROM faults. The safety monitor component 142 can include other controller's safety mechanisms such as parity checking, CRC, ECC, SECDED timeout monitoring, voltage monitoring, and temperature sensors.

Host notifications 220 illustrates three possible error notification paths to the host system 120. These include a link drop to the host system, error notification on a sideband signal, and host error response. Any other suitable notification method can also be provided to notify the host about ROM faults.

During ROM execution, the safety monitor component 142 continuously monitors for faults using various safety mechanisms. If a fault is detected during ROM execution, it is immediately flagged through the ROM fault notification 216. ROM fault checks can be triggered at different stages, such as during initial ROM execution, after a processor becomes idle, and/or before any host read/write operations begin. This flexible timing allows for optimal boot performance while maintaining robust fault detection.

Each CPU block can initiate fault checks on or using other CPUs, as indicated by the arrows between ROM execution blocks for the various processors shown in FIG. 2. This creates a comprehensive fault detection network where processors can monitor each other's ROM integrity. In some cases, the ROM fault checks occur before any host read/write operations, ensuring no corrupted data transfer can take place. This is shown by the “ROM fault check before HOST RD/WR” path connecting to the error notification section.

Each ROM execution block can operate independently while maintaining coordination through the safety monitor component 142, which ensures all fault detection and notification processes are properly managed. The diagram 204 shows both hardware-controlled paths (solid lines) and firmware-controlled paths (dotted lines), illustrating the system's flexibility in implementing fault detection through multiple mechanisms.

This architecture is particularly suited for automotive applications requiring functional safety compliance, as it provides comprehensive fault detection while optimizing boot time through efficient parallel processing.

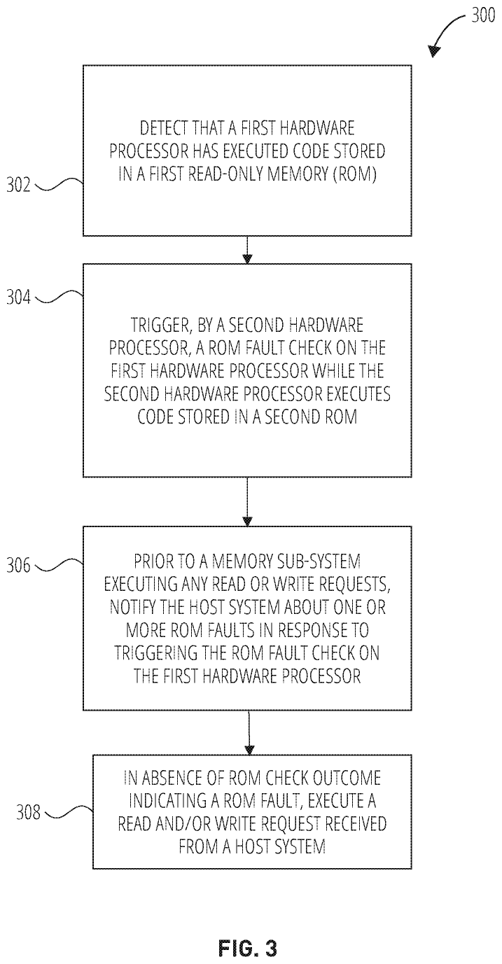

FIG. 3 illustrates a diagram 300 of operations performed using the safety monitor component 142, in accordance with some examples. The method or process of diagram 300 can be performed by processing logic that can include hardware (e.g., a processing device, circuitry, dedicated logic, programmable logic, microcode, hardware of a device, an integrated circuit, etc.), software (e.g., instructions run or executed on a processing device), or a combination thereof. In some examples, the method or process of diagram 300 is performed by the memory sub-system controller 115, local media controllers 135, and/or subcomponents of the memory sub-system controller 115 and/or local media controllers 135 of FIG. 1. In these examples, the method or process of diagram 300 can be performed, at least in part, by the safety monitor component 142. Although the processes are shown in a particular sequence or order, unless otherwise specified, the order of the processes can be modified. Thus, the illustrated examples should be understood only as examples; the illustrated processes can be performed in a different order, and some processes can be performed in parallel. Additionally, one or more processes can be omitted in various examples. Thus, not all processes are required in every example, other process flows are possible.

Referring now to FIG. 3, the method begins at operation 302 with detecting that a first hardware processor has executed code stored in a first ROM. This detection occurs after the first hardware processor completes its ROM execution sequence, such as, during the boot sequence.

At operation 304, in response to detecting that the first hardware processor has executed the code stored in the first ROM, a second hardware processor triggers a ROM fault check on the first hardware processor (e.g., while the second hardware processor executes code stored in a second ROM or independent of the second hardware processor executing the code stored in the second ROM). In an example, this parallel processing approach optimizes boot time by allowing fault detection to occur simultaneously with other operations.

At operation 306, prior to the memory system 110 executing any read or write requests received from a host system 120, the memory system 110 notifies the host system about one or more ROM faults, such as in response to triggering the ROM fault check on the first hardware processor. This notification can occur through multiple channels, including memory device error responses, sideband signals (GPIO), or link drops.

At operation 308, the memory system 110, in absence of ROM check outcome indicating a ROM fault, executes a read and/or write request received from a host system 120.

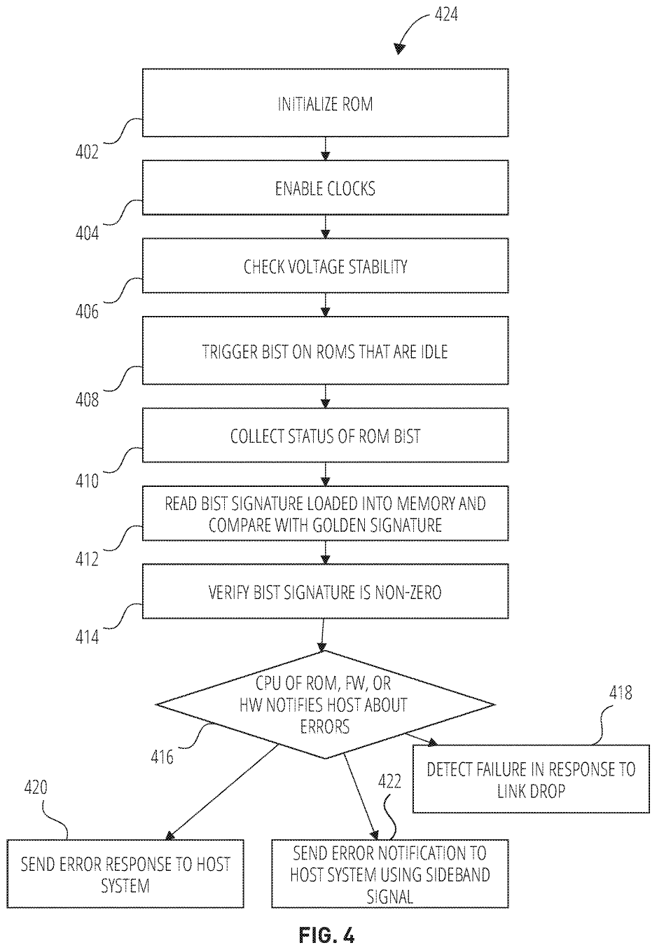

FIG. 4 illustrates a diagram of a routine 424 (process or method) performed using the safety monitor component 142, in accordance with some examples. The routine 424 details the ROM fault check sequence and notification process performed by the safety monitor component 142. The method begins at operation 402 with ROM initialization, followed by operation 404 where the system enables one or more system or device clocks.

At operation 406, the system performs voltage stability checks to ensure proper operating conditions before proceeding with fault detection. Operation 408 then triggers BIST on ROMs that are currently idle, allowing for efficient parallel processing during the boot sequence.

The process continues at operation 410 where the system collects the status of BIST operations. For example, at operation 412, the system can read a BIST signature loaded into memory and compares it with a golden signature to verify integrity. Operation 414 performs an additional verification step to ensure the BIST signature is non-zero, preventing false positive results.

Following signature verification, the process reaches a decision point at operation 416 where CPU associated with the ROM, firmware, or hardware notifies the host system 120 about any errors through one of three paths. The first path leads to operation 420, where the system sends an error response directly to the host system. The second path, shown by operation 422, involves sending error notifications through a sideband signal (GPIO) for improved response time to the automotive control system.

The third path, represented by operation 418, handles cases where a processor becomes non-functional due to ROM faults. In this scenario, the system detects failure through a link drop, which prevents any potential corrupted data transfer between the host and memory device. This comprehensive notification system ensures that all ROM faults are detected and properly communicated before any data transfer occurs.

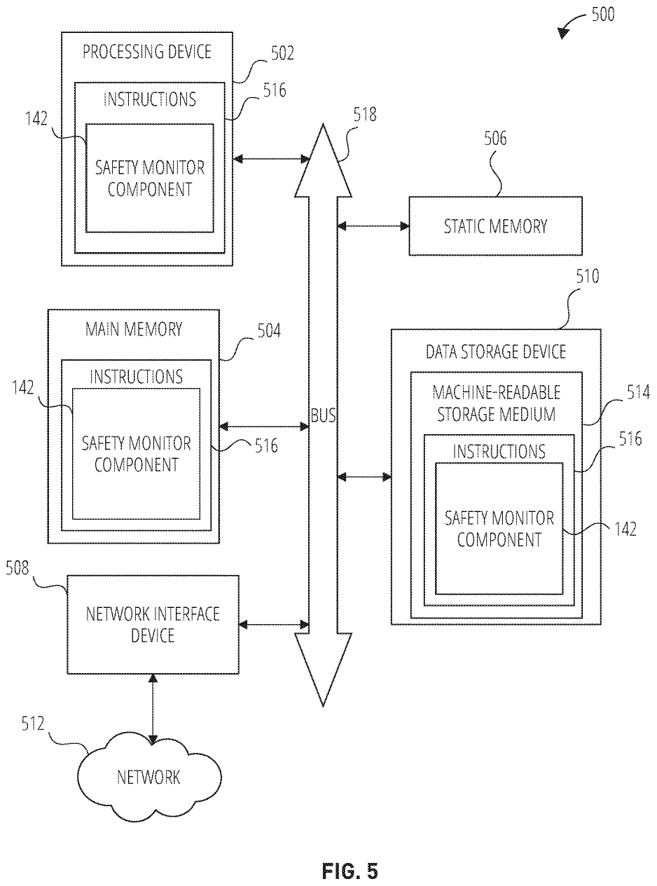

FIG. 5 illustrates an example machine in the form of a computer system 500 within which a set of instructions can be executed for causing the machine to perform any one or more of the methodologies discussed herein. In some examples, the computer system 500 can correspond to a host system (e.g., the host system 120 of FIG. 1) that includes, is coupled to, or utilizes a memory system (e.g., the memory system 110 of FIG. 1) or can be used to perform the operations described herein. In alternative examples, the machine can be connected (e.g., networked) to other machines in a local area network (LAN), an intranet, an extranet, and/or the Internet. The machine can operate in the capacity of a server or a client machine in a client-server network environment, as a peer machine in a peer-to-peer (or distributed) network environment, or as a server or a client machine in a cloud computing infrastructure or environment.

The machine can be a personal computer (PC), a tablet PC, a set-top box (STB), a Personal Digital Assistant (PDA), a cellular telephone, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 500 includes a processing device 502, a main memory 504 (e.g., ROM, flash memory, DRAM such as SDRAM or Rambus DRAM (RDRAM), etc.), a static memory 506 (e.g., flash memory, static random access memory (SRAM), etc.), and a data storage device 510, which communicate with each other via a bus 518.

The processing device 502 represents one or more general-purpose processing devices such as a microprocessor, a central processing unit, or the like. More particularly, the processing device 502 can be a complex instruction set computing (CISC) microprocessor, a reduced instruction set computing (RISC) microprocessor, a very long instruction word (VLIW) microprocessor, a processor implementing other instruction sets, or processors implementing a combination of instruction sets. The processing device 502 can also be one or more special-purpose processing devices such as an application-specific integrated circuit (ASIC), a field programmable gate array (FPGA), a digital signal processor (DSP), a network processor, or the like. The processing device 502 is configured to execute instructions 516 for performing the operations and steps discussed herein. The computer system 500 can further include a network interface device 508 to communicate over a network 512.

The data storage device 510 can include a machine-readable storage medium 514 (also known as a computer-readable medium) on which is stored one or more sets of instructions 516 or software embodying any one or more of the methodologies or functions described herein. The instructions 516 can also reside, completely or at least partially, within the main memory 504 and/or within the processing device 502 during execution thereof by the computer system 500, the main memory 504 and the processing device 502 also constituting machine-readable storage media. The machine-readable storage medium 514, data storage device 510, and/or main memory 504 can correspond to the memory system 110 of FIG. 1.

In one example, the instructions 516 include instructions to implement functionality corresponding to providing various memory operations as described herein (e.g., the safety monitor component 142 of FIG. 1). While the machine-readable storage medium 514 is shown in an example to be a single medium, the term “machine-readable storage medium” should be taken to include a single medium or multiple media that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media.

Described implementations of the subject matter can include one or more features, alone or in combination as illustrated below by way of examples.

Example 1. A system comprising: a memory system comprising a plurality of hardware processors; a first hardware processor of the plurality of hardware processors having a first read-only memory (ROM), the first hardware processor configured to execute ROM code from the first ROM; and a second hardware processor of the plurality of hardware processors having a second ROM, the second hardware processor programmed to perform various operations. For example, the second hardware processor can detect that the first hardware processor has executed at least a portion of code stored in the first ROM; in response to detecting that the first hardware processor has executed at least the portion of the code stored in the first ROM, trigger a ROM fault check on the first hardware processor; and notify a host system about one or more ROM faults in response to triggering the ROM fault check on the first hardware processor.

Example 2. The system of Example 1, wherein triggering the ROM fault check on the first hardware processor is performed while the second hardware processor executes code stored in the second ROM and comprises: performing a firmware read and compare with known-good ROM code, wherein the second hardware processor, in absence of a ROM fault notification about the first hardware processor, executes a read or write request received from the host system.

Example 3. The system of any one of Examples 1-2, wherein triggering the ROM fault check on the first hardware processor comprises: performing a memory built-in self-test (MBIST) operation associated with the first hardware processor using fault detection hardware associated with the first hardware processor.

Example 4. The system of any one of Examples 1-3, wherein notifying the host system comprises at least one of: sending a memory system error response; asserting a sideband signal; or dropping a link between the memory system and the host system.

Example 5. The system of Example 4, wherein sending the memory system error response comprises: accessing a read or write command from the host system in a command queue; attempting to execute the read or write command from the command queue; and sending the memory system error response to the host system in response to detecting failure in execution of the read or write command.

Example 6. The system of any one of Examples 1-5, wherein the first hardware processor comprises a power management unit (PMU) processor and the second hardware processor comprises a high-speed (HS) processor or channel processor coupled between a memory controller and a memory device of the memory system.

Example 7. The system of any one of Examples 1-6, wherein the memory system further comprises a safety controller configured to detect ROM faults during ROM execution.

Example 8. The system of Example 7, wherein the safety controller is configured to detect a ROM fault using at least one of: parity checking, cyclic redundancy check (CRC), error correction code (ECC), single error correction double error detection (SECDED), or timeout monitoring.

Example 9. The system of any one of Examples 1-8, wherein a controller of the memory system is programmed to verify a fault check signature of the first hardware processor.

Example 10. The system of Example 9, the operations comprising: in response to detecting the one or more ROM faults based on verifying the fault check signature, notifying the host system prior to executing any read or write requests from the host system.

Example 11. The system of any one of Examples 1-10, wherein second hardware processor is programmed to verify a fault check signature of the first hardware processor.

Example 12. The system of any one of Examples 1-11, wherein the ROM fault check is triggered on the first hardware processor in response to determining by the second hardware processor that the first hardware processor is idle.

Example 13. The system of Example 12, wherein the ROM fault check is triggered on the first hardware processor in response to determining by the second hardware processor that the first hardware processor has completed executing all of the code stored in the first ROM.

Example 14. The system of any one of Examples 1-13, wherein the memory system receives a vendor-specific (VS) command from the host system to trigger the ROM fault check on the first and second hardware processors.

Example 15. The system of Example 14, wherein the VS command is received during mission mode.

Example 16. The system of any one of Examples 14-15, wherein the VS command comprises a reset or reboot command.

Example 17. The system of any one of Examples 1-16, wherein the ROM fault check is triggered during device initialization through at least one of: hardware, ROM, or firmware.

Example 18. The system of any one of Examples 1-17, wherein the first hardware processor is programmed to: detect that the second hardware processor has executed code stored in the second ROM; in response to detecting that the second hardware processor has executed the code stored in the second ROM, trigger, by the first hardware processor, an additional ROM fault check on the second hardware processor; and prior to the memory system executing any read or write requests received from the host system, notify the host system about one or more ROM faults in response to triggering the additional ROM fault check on the second hardware processor.

Example 19. At least one non-transitory machine-readable storage medium comprising instructions that, when executed by a processing device, cause the processing device to: detect that a first hardware processor has executed at least a portion of code stored in a first read-only memory (ROM); in response to detecting that the first hardware processor has executed at least the portion of the code stored in the first ROM, trigger, by a second hardware processor, a ROM fault check on the first hardware processor; and notify a host system about one or more ROM faults in response to triggering the ROM fault check on the first hardware processor.

Example 20. The non-transitory machine-readable storage medium of Example 19, wherein the first hardware processor comprises a power management unit (PMU) processor and the second hardware processor comprises a high-speed (HS) processor or channel processor coupled between a memory controller and a memory device of the memory system, and wherein the memory system further comprises a safety controller configured to detect ROM faults during ROM execution.

Example 21. The non-transitory machine-readable storage medium of any one of Examples 19-20, wherein the ROM fault check is triggered during device initialization through at least one of: hardware, ROM, or firmware, and wherein the first hardware processor is programmed to: detect that the second hardware processor has executed code stored in the second ROM; in response to detecting that the second hardware processor has executed the code stored in the second ROM, trigger, by the first hardware processor, an additional ROM fault check on the second hardware processor; and prior to the memory system executing any read or write requests received from the host system, notify the host system about one or more ROM faults in response to triggering the additional ROM fault check on the second hardware processor.

Example 22. A method comprising: detecting that a first hardware processor has executed at least a portion of code stored in a first read-only memory (ROM); in response to detecting that the first hardware processor has executed at least the portion of the code stored in the first ROM, triggering, by a second hardware processor, a ROM fault check on the first hardware processor; and notifying a host system about one or more ROM faults in response to triggering the ROM fault check on the first hardware processor.

Example 23. The method of Example 22, wherein the first hardware processor comprises a power management unit (PMU) processor and the second hardware processor comprises a high-speed (HS) processor or channel processor coupled between a memory controller and a memory device of the memory system, and wherein the memory system further comprises a safety controller configured to detect ROM faults during ROM execution.

Example 24. The method of any one of Examples 22-23, comprising: detecting that the second hardware processor has executed code stored in the second ROM; in response to detecting that the second hardware processor has executed the code stored in the second ROM, triggering, by the first hardware processor, an additional ROM fault check on the second hardware processor; and prior to the memory system executing any read or write requests received from the host system, notifying the host system about one or more ROM faults in response to triggering the additional ROM fault check on the second hardware processor.

Each of these non-limiting examples or embodiments can stand on its own or can be combined in various permutations or combinations with one or more of the other examples or embodiments discussed herein.

The term “coupled with” generally refers to a connection between components, which can be an indirect communicative connection or direct communicative connection (e.g., without intervening components), whether wired or wireless, including connections such as electrical, optical, magnetic, and the like.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities. Usually, though not necessarily, these quantities take the form of electrical or magnetic signals capable of being stored, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. The present disclosure can refer to the action and processes of a computer system, or similar electronic computing device, that manipulates and transforms data represented as physical (electronic) quantities within the computer system's registers and memories into other data similarly represented as physical quantities within the computer system memories or registers or other such information storage systems.

The present disclosure also relates to an apparatus for performing the operations herein. This apparatus can be specially constructed for the intended purposes, or it can include a general purpose computer selectively activated or reconfigured by a computer program stored in the computer. Such a computer program can be stored in a computer-readable storage medium, such as, but not limited to, any type of disk including floppy disks, optical disks, CD-ROMs, and magnetic-optical disks, ROMs, RAMs, EPROMs, EEPROMs, magnetic or optical cards, or any type of media suitable for storing electronic instructions, each coupled to a computer system bus.

The algorithms and displays presented herein are not inherently related to any particular computer or other apparatus. Various general-purpose systems can be used with programs in accordance with the teachings herein, or it can prove convenient to construct a more specialized apparatus to perform the method. The structure for a variety of these systems will appear as set forth in the description below. In addition, the present disclosure is not described with reference to any particular programming language. It will be appreciated that a variety of programming languages can be used to implement the teachings of the disclosure as described herein.

The present disclosure can be provided as a computer program product, or software, that can include a machine-readable medium (such as a non-transitory machine-readable medium) having stored thereon instructions, which can be used to program a computer system (or other electronic devices) to perform a process according to the present disclosure. A machine-readable medium includes any mechanism for storing information in a form readable by a machine (e.g., a computer). In some examples, a machine-readable (e.g., computer-readable) medium includes a machine (e.g., a computer) readable storage medium such as a ROM, RAM, magnetic disk storage media, optical storage media, flash memory components, and so forth. A machine-readable storage medium can be non-transitory (in other words, not having any transitory signals) in that it does not embody a propagating signal. However, labeling a machine-readable storage medium “non-transitory” should not be construed to mean that the machine-readable storage medium is incapable of movement; the machine-readable storage medium should be considered as being transportable from one physical location to another.

In the foregoing specification, examples of the disclosure have been described with reference to specific examples thereof. It will be evident that various modifications can be made thereto without departing from the broader scope of examples of the disclosure as set forth in the following claims. The specification and drawings are, accordingly, to be regarded in an illustrative sense rather than a restrictive sense.

What is claimed is:

1. A system comprising:
a memory system comprising a plurality of hardware processors;
a first hardware processor of the plurality of hardware processors having a first read-only memory (ROM), the first hardware processor configured to execute ROM code from the first ROM; and
a second hardware processor of the plurality of hardware processors having a second ROM, the second hardware processor programmed to perform operations comprising:
detecting that the first hardware processor has executed at least a portion of code stored in the first ROM;
in response to detecting that the first hardware processor has executed at least the portion of the code stored in the first ROM, triggering a ROM fault check on the first hardware processor; and
notifying a host system about one or more ROM faults in response to triggering the ROM fault check on the first hardware processor.

2. The system of claim 1, wherein triggering the ROM fault check on the first hardware processor is performed while the second hardware processor executes code stored in the second ROM and comprises:
performing a firmware read and compare with known-good ROM code, wherein the second hardware processor is programmed to perform operations comprising, in absence of a ROM fault notification about the first hardware processor, executing a read or write request received from the host system.

3. The system of claim 1, wherein triggering the ROM fault check on the first hardware processor comprises:
performing a memory built-in self-test (MBIST) operation associated with the first hardware processor using fault detection hardware associated with the first hardware processor.

4. The system of claim 1, wherein notifying the host system comprises at least one of:
sending a memory system error response;
asserting a sideband signal; or
dropping a link between the memory system and the host system.

5. The system of claim 4, wherein sending the memory system error response comprises:
accessing a read or write command from the host system in a command queue;
attempting to execute the read or write command from the command queue; and
sending the memory system error response to the host system in response to detecting failure in execution of the read or write command.

6. The system of claim 1, wherein the first hardware processor comprises a power management unit (PMU) processor and the second hardware processor comprises a high-speed (HS) processor or channel processor coupled between a memory controller and a memory device of the memory system.

7. The system of claim 1, wherein the memory system further comprises a safety controller configured to detect ROM faults during ROM execution.

8. The system of claim 7, wherein the safety controller is configured to detect a ROM fault using at least one of: parity checking, cyclic redundancy check (CRC), error correction code (ECC), single error correction double error detection (SECDED), or timeout monitoring.

9. The system of claim 1, wherein a controller of the memory system is programmed to perform operations comprising:
verifying a fault check signature of the first hardware processor.

10. The system of claim 9, the operations comprising:
in response to detecting the one or more ROM faults based on verifying the fault check signature, notifying the host system prior to executing any read or write requests from the host system.

11. The system of claim 1, wherein second hardware processor is programmed to perform operations comprising:
verifying a fault check signature of the first hardware processor.

12. The system of claim 1, wherein the ROM fault check is triggered on the first hardware processor in response to determining by the second hardware processor that the first hardware processor is idle.

13. The system of claim 12, wherein the ROM fault check is triggered on the first hardware processor in response to determining by the second hardware processor that the first hardware processor has completed executing all of the code stored in the first ROM.

14. The system of claim 1, wherein the memory system receives a vendor-specific (VS) command from the host system to trigger the ROM fault check on the first and second hardware processors.

15. The system of claim 14, wherein the VS command is received during mission mode.

16. The system of claim 14, wherein the VS command comprises a reset or reboot command.

17. The system of claim 1, wherein the ROM fault check is triggered during device initialization through at least one of: hardware, ROM, or firmware.

18. The system of claim 1, wherein the first hardware processor is programmed to perform operations comprising:
detecting that the second hardware processor has executed code stored in the second ROM;
in response to detecting that the second hardware processor has executed the code stored in the second ROM, triggering, by the first hardware processor, an additional ROM fault check on the second hardware processor; and
prior to the memory system executing any read or write requests received from the host system, notifying the host system about one or more ROM faults in response to triggering the additional ROM fault check on the second hardware processor.

19. At least one non-transitory machine-readable storage medium comprising instructions that, when executed by a processing device, cause the processing device to perform operations comprising:
detecting that a first hardware processor has executed at least a portion of code stored in a first read-only memory (ROM);
in response to detecting that the first hardware processor has executed at least the portion of the code stored in the first ROM, triggering, by a second hardware processor, a ROM fault check on the first hardware processor; and
notifying a host system about one or more ROM faults in response to triggering the ROM fault check on the first hardware processor.

20. The non-transitory machine-readable storage medium of claim 19, wherein the first hardware processor comprises a power management unit (PMU) processor and the second hardware processor comprises a high-speed (HS) processor or channel processor coupled between a memory controller and a memory device of the memory system, and wherein the memory system further comprises a safety controller configured to detect ROM faults during ROM execution.

21. The non-transitory machine-readable storage medium of claim 19, wherein the ROM fault check is triggered during device initialization through at least one of: hardware, ROM, or firmware, and wherein the first hardware processor is programmed to perform operations comprising:
detecting that the second hardware processor has executed code stored in the second ROM;
in response to detecting that the second hardware processor has executed the code stored in the second ROM, triggering, by the first hardware processor, an additional ROM fault check on the second hardware processor; and
prior to the memory system executing any read or write requests received from the host system, notifying the host system about one or more ROM faults in response to triggering the additional ROM fault check on the second hardware processor.

22. A method comprising:
detecting that a first hardware processor has executed at least a portion of code stored in a first read-only memory (ROM);
in response to detecting that the first hardware processor has executed at least the portion of the code stored in the first ROM, triggering, by a second hardware processor, a ROM fault check on the first hardware processor; and
notifying a host system about one or more ROM faults in response to triggering the ROM fault check on the first hardware processor.

23. The method of claim 22, wherein the first hardware processor comprises a power management unit (PMU) processor and the second hardware processor comprises a high-speed (HS) processor or channel processor coupled between a memory controller and a memory device of the memory system, and wherein the memory system further comprises a safety controller configured to detect ROM faults during ROM execution.

24. The method of claim 22, comprising:
detecting that the second hardware processor has executed code stored in the second ROM;
in response to detecting that the second hardware processor has executed the code stored in the second ROM, triggering, by the first hardware processor, an additional ROM fault check on the second hardware processor; and
prior to the memory system executing any read or write requests received from the host system, notifying the host system about one or more ROM faults in response to triggering the additional ROM fault check on the second hardware processor.
